(19) United States
(12) Patent Application Publication
(10) Pub. No.: US 2025/0096082 A1
(43) Pub. Date: Mar. 20, 2025

(54) INTERCONNECT CLIP FOR VERTICALLY STACKED DIE ARRANGEMENT

(71) Applicant: Infineon Technologies AG, Neubiberg (DE)

(72) Inventors: Mei Yih Goh, Melaka (MY); Chee Voon Tan, Seremban (MY); Sung Hoe Yeong, Port Klang (MY); Michael Stadler, München (DE)

(21) Appl. No.: 18/369,443

(22) Filed: Sep. 18, 2023

(51) Int. Cl. H01L 23/495; H01L 23/00; H01L 25/07

(52) U.S. Cl. CPC H01L 23/49562; H01L 23/49582; H01L 24/32; H01L 24/83; H01L 25/074; H01L 2224/32245; H01L 2224/83815

(57) ABSTRACT

An electrical interconnect clip includes a die interface portion that is adapted for mating in between two vertically stacked semiconductor dies, and a carrier connection portion that is configured to electrically connect the two vertically stacked semiconductor dies with a carrier,
wherein the die interface portion comprises a lower mating surface, an upper mating surface opposite from the lower mating surface, and a solder retention feature formed by one or more grooves in the upper mating surface that are spaced apart from the outer edge sides of the electrical interconnect clip and surround a die attach area of the upper mating surface.

### BACKGROUND

Many applications such as automotive and industrial applications utilize semiconductor packages to accommodate high voltage loads. These semiconductor packages can be configured as discrete components or may be configured as power converter circuits such as single and multi-phase half-wave rectifiers, single and multi-phase full-wave rectifiers, voltage regulators, etc. These semiconductor packages can include power devices such as diodes, IGBTs (insulated gate bipolar transistors), MOSFETs (metal oxide semiconductor field effect transistors), HEMTs (high electron mobility transistors), etc. Thermal and electrical performance play an increasing role in the advancement of semiconductor packages. Many power semiconductor packages require electrical connections with low electrical resistance and high current capacity that can be formed reliably and inexpensively.

### SUMMARY

An electrical interconnect clip is disclosed. According to an embodiment, the electrical interconnect clip comprises a die interface portion that is adapted for mating in between two vertically stacked semiconductor dies, and a carrier connection portion that is configured to electrically connect the two vertically stacked semiconductor dies with a carrier, wherein the die interface portion comprises a lower mating surface, an upper mating surface opposite from the lower mating surface, and a solder retention feature formed by one or more grooves in the upper mating surface that are spaced apart from the outer edge sides of the electrical interconnect clip and form a border surrounding a die attach area of the upper mating surface.

A method of forming a semiconductor package is disclosed. According to an embodiment, the method comprises providing a carrier comprising a die pad and a plurality of leads, providing first and second semiconductor dies, each being configured as vertical power devices, providing a electrical interconnect clip that comprises a die interface portion and a carrier connection portion, proving a stacked die arrangement on the die pad that comprises the die interface portion of the electrical interconnect clip arranged between the first and second semiconductor dies and the carrier connection portion contacting the carrier, providing solder material in between the second semiconductor die and the die interface portion of the electrical interconnect clip, and performing a soldering process that liquifies the solder material, wherein the electrical interconnect clip comprises a solder retention feature that forms a border at least partially surrounding the second semiconductor die, and wherein the solder retention feature interacts with liquified solder during the soldering process by retaining the solder material within a confined space that surrounds the second semiconductor die, thereby preventing floating movement of the second semiconductor die.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1, which includes FIGS. 1A, 1B, 1C and 1D, illustrates an electrical interconnect clip, according to an embodiment. FIG. 1A illustrates the electrical interconnect clip from a plan view perspective, FIG. 1B illustrates the electrical interconnect clip from a side view perspective along a width direction, FIG. 1C illustrates the electrical interconnect clip from a side view perspective looking along a lengthwise direction, and FIG. 1D illustrates the electrical interconnect clip along the cross-sectional line I-I′ identified in FIG. 1A.

FIG. 2 illustrates a semiconductor package assembly comprising multiple stacked die arrangements with electrical interconnect clips forming electrical connections between the stacked dies and the carrier.

FIG. 3, which includes FIGS. 3A, 3B, 30, illustrates an electrical interconnect clip, according to different embodiments.

### DETAILED DESCRIPTION

Embodiments of an electrical interconnect clip, a method of forming a semiconductor package using the electrical interconnect clip, and a corresponding semiconductor package are disclosed herein. The semiconductor package includes a stacked die arrangement with two semiconductor dies stacked on top of one another and mounted on a carrier. The electrical interconnect clip is inserted between the two semiconductor dies and forms an electrical connection with terminals from both of the dies and the carrier. The electrical interconnect clip advantageously comprises a solder retention feature formed by a groove or set of grooves that surround the die attach area of the upper semiconductor die. The solder retention feature receives and retains excess solder that flows out from the upper semiconductor die during a soldering process. This retention of the excess solder material prohibits floating moment of the upper semiconductor die while the solder material is in a liquified state, thereby maintaining the position of the upper semiconductor die in its desired location. The provision of the solder retention feature may eliminate the need for providing a special plating on the electrical interconnect clip and thus reduce cost.

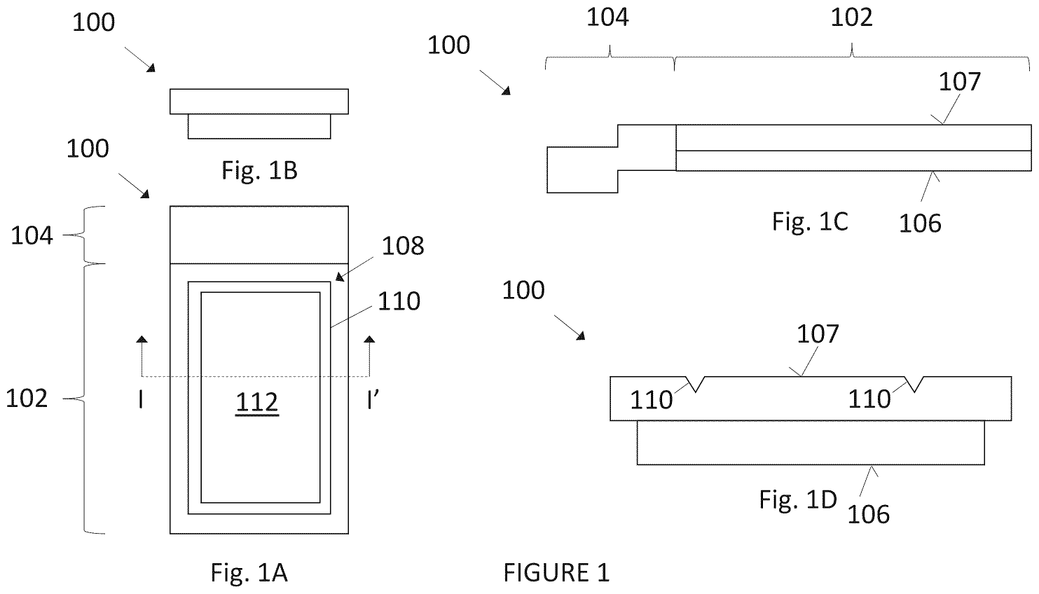

Referring to FIG. 1, an electrical interconnect clip 100 is shown. The electrical interconnect clip 100 is an electrical interconnect clip that is used to form a low resistance electrical connection in a semiconductor package. The electrical interconnect clip 100 may be formed from an undisturbed planar sheet of the base material that is similar or identical to a metal sheet used to form a lead frame. The geometric features of the electrical interconnect clip 100 described herein may be created by performing metal processing steps such as punching, coining, stamping, etching, bending, cutting, etc. The electrical interconnect clip 100 may be formed from an electrically and thermally conductive base material such as copper, aluminum, and alloys thereof. The electrical interconnect clip 100 may be plated with additional metals, e.g., Ni, Ag, Au, Pd, Pt, Ni, etc., which may act as adhesion promotors, anti-corrosion layers, etc. However, in embodiments these plating layers may be omitted such that the base material is exposed.

The electrical interconnect clip 100 comprises a die interface portion 102 and a carrier connection portion 104. The die interface portion 102 is adapted for mating in between two vertically stacked semiconductor dies. That is, the die interface portion 102 is configured to interface with one semiconductor die below it and one semiconductor die above it. To this end, the die interface portion 102 comprises a lower mating surface 106 and an upper mating surface 107 opposite from the lower mating surface 106. The lower mating surface 106 and the upper mating surface 107 are each substantially planar surfaces that can be arranged to be flush against a semiconductor die. The carrier connection portion 104 corresponds to an outer part of the electrical interconnect clip 100 that facilitates an electrical connection with an external carrier. The carrier connection portion 104 forms a vertical transition between the die interface portion 102 and an outer end of the carrier connection portion 104 that is below the die interface portion 102 and used to contact the external carrier. As shown, the carrier connection portion 104 comprises a perpendicular transition which may correspond to a punch in the metal. More generally, the carrier connection portion 104 may comprise different geometries such as curved transitions, rounded corners, etc.

The die interface portion 102 of the electrical interconnect clip 100 comprises a solder retention feature 108 formed by a groove 110 in the upper mating surface 107. The groove 110 is an intentionally formed trench-like structure that extends inward from the upper mating surface 107 of the electrical interconnect clip 100 towards the lower mating surface 106. The groove 110 can be created by processing an initially planar metal surface using a metal processing technique, e.g., coining, etching, cutting, stamping, etc. to remove metal or other otherwise disturb the planarity of the surface. The groove 110 is spaced apart from the outer edge sides of the electrical interconnect clip 100. That is, the groove 110 is fully confined within an interior region of the upper mating surface 107. A separation distance between the groove 110 and the outer edge sides of the electrical interconnect clip 100 may be between 25 μm and 100 μm, for example. The groove 110 surrounds a die attach area of the upper mating surface 107.

According to an embodiment, the solder retention feature 108 is formed by a continuous groove 110 that forms an enclosed shape around the die attach area 112 in the upper mating surface 107. That is, the solder retention feature 108 completely surrounds the die attach area 112 on the upper mating surface 107. FIG. 1 illustrates one example of such an embodiment. In this embodiment, the groove 110 forms a rectangle around the die attach area 112 of the upper mating surface 107. As will be explained in further detail below, other geometries are possible.

According to an embodiment, the groove 110 has a depth of between 10 μm and 50 μm. In a particular embodiment, the depth of the groove 110 is about 20-25 μm. The depth refers to the distance between the upper mating surface 107 and the lowest point of the groove 110 that is closest to the lower mating surface 106.

According to an embodiment, the groove 110 has v-shaped cross-sectional geometry. FIG. 1 illustrates one example of a groove 110 with a v-shaped cross-sectional geometry. A v-shaped cross-sectional geometry refers to a geometry wherein the walls of the groove 110 are planar and intersect one another at an acute point. According to an embodiment, an angle of intersection between sidewalls of the groove 110 is between 50° and 70°. In a particular embodiment, the angle of intersection between sidewalls of the groove 110 with a V-shaped cross-sectional geometry is about 60°. Other cross-sectional geometries are possible. For example, the groove 110 may have a u-shaped cross-sectional geometry, a trapezoid-shaped cross-sectional geometry, a flat-bottomed cross-sectional geometry, a completely curved cross-sectional geometry, a cross-sectional geometry with planar sidewalls, a cross-sectional geometry wherein the outer walls have convex or concave shape, or a cross-sectional geometry wherein the outer walls form rounded transitions with the bottom of the grooves 110 and/or the upper mating surface 107.

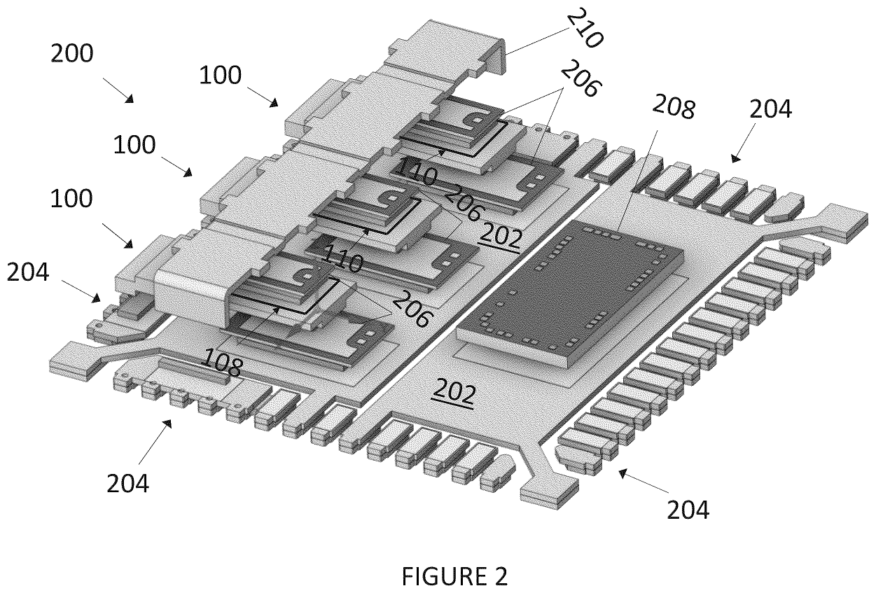

Referring to FIG. 2, an exploded view of an assembly 200 for forming a semiconductor package is shown, according to an embodiment. The assembly 200 comprises a carrier comprising die pads 202 and a plurality of leads 204. According to an embodiment, the carrier is provided from a metal lead frame. This lead frame may be formed from one or more conductive metals such as Cu, Ni and/or Ag, for example. Additionally, the features of the lead frame may include or be plated with Cu, Ni, Ag, Au, Pd, Pt, NiV, NiP, NiNiP, NiP/Pd, Ni/Au, NiP/Pd/Au, or NiP/Pd/AuAg, for example. The lead frame may be provided from a uniform thickness planar sheet metal and processed by metal processing techniques, e.g., stamping, cutting, etching, etc. Instead of a metal lead frame, the carrier may correspond to an insulated electronics substrate. Examples of insulated electronics substrates include PCBs (printed circuit boards) or power electronics carriers such as DCBs (direct copper bonded) substrates, IMS (insulated metal) substrates, or AMB (active metal brazed) substrates. In that case, the carrier may additionally comprise one or more electrically insulating regions formed from, e.g., ceramic, FR-4, etc., with a structured metal layer disposed thereon.

The assembly 200 comprises a plurality of semiconductor dies mounted on the die pad portion of the carrier. The semiconductor dies include pairs of vertical power device dies 206 mounted in vertically stacked arrangements. The vertical power device dies 206 are discrete power devices that are rated to accommodate voltages of at least 100 V (volts), e.g., voltages of 600 V, 1200 V or more and/or are rated to accommodate currents of at least 1A, e.g., currents of 10A, 50A, 100A or more. Examples of vertical power device dies 206 include diodes, transistors, thyristors, junction field effect transistors, etc. In a particular example, the vertical power device dies 206 are configured as MOSFETs (Metal Oxide Semiconductor Field Effect Transistors), IGBTs (Insulated Gate Bipolar Transistors), or HEMTs (High Electron Mobility Transistors). The term vertical refers to the fact that the power device dies conduct current in a vertical direction between a first load terminal disposed on a main surface and a second load terminal disposed on the rear surface opposite from the main surface. The first and second load terminals may respectively correspond to the source and drain terminals (or vice-versa) in the case of a MOSFET and may respectively correspond to the emitter and collector terminals (or vice-versa) in the case of an IGBT, and so forth. The assembly 200 additionally comprises an additional logic device die 208 mounted on a low voltage plane separate from the vertically stacked arrangements. The logic device die 208 may be an integrated circuit, such as a silicon logic die, for example.

According to an embodiment, the vertically stacked arrangements of semiconductor dies are each configured as a half bridge circuit. A half-bridge circuit refers to one type of circuit topology that is used in a power conversion circuit, such as a DC to DC converter, DC to AC converter, etc. In a half bridge circuit, one load terminal of the high-side switch (e.g., the source/emitter) is connected to a first DC voltage (e.g., a positive potential), one load terminal of the low-side switch (e.g., the drain/collector) is connected to a second DC voltage (e.g., negative potential or ground), and the remaining two load terminals (e.g., the drain/collector of the high-side switch and the source/emitter of the low-side switch) are connected together to form the output or switch (‘SW’) of the half-bridge circuit. The control (gate) terminals of the high-side and low-side switch can be switched according to a power control scheme (e.g., pulse width modulation) to produce a desired voltage and frequency at the output of the half-bridge circuit. For example, a first one of the vertical power device dies 206 mounted directly on the die pad 202 may correspond to a high-side switch of the half bridge circuit, and a second one of the vertical power device dies 206 mounted above the first one of the vertical power device dies 206 may correspond to the low-side switch of the half bridge circuit. The logic device die 208 may be configured to provide the switching signal to the control terminals of the high-side and low-side switch. Electrical interconnection between the logic device die 208 and the vertically stacked arrangements of semiconductor dies may be provided by additional electrical interconnect elements, e.g., bond wires, clips, ribbons, etc., that are not shown in the figure. As shown, the semiconductor package assembly 200 comprises three of the vertically stacked arrangements of semiconductor dies. This configuration may be used to create a full-bridge arrangement, wherein each of the vertically stacked arrangements of semiconductor forms one phase of the full-bridge arrangement.

Each of the vertically stacked arrangements are mounted in the following way. A first one of the vertical power device dies 206 is mounted on the die pad 202 with a first load terminal (e.g., a source terminal) facing the die pad 202 and a second load terminal (e.g., a drain terminal) facing away from the die pad 202. The die interface portion 102 of the electrical interconnect clip is arranged over the first one of the vertical power device dies 206 with the lower mating surface 106 facing the second load terminal of the first vertical power device die 206. A second one of the vertical power device dies 206 is mounted on the die interface portion 102 of the electrical interconnect clip 100 with a first load terminal facing (e.g., a drain terminal) the electrical interconnect clip 100 and a second load terminal (e.g., a source terminal) facing away from the electrical interconnect clip 100. A second electrical interconnect clip 210 is provided above the second vertical power device die 206 and mated with the second load terminal of the second vertical power device die 206. In this arrangement, the first load terminal of the first vertical power device die 206 is electrically connected to the die pad 202, which in turn is connected to the leads 204, the second load terminal of the second vertical power device die 206 is electrically connected to the leads 204 via the second electrical interconnect clip 210, and the second load terminal of the first vertical power device die 206 and the first load terminal of the second vertical power device die 206 are each electrically connected to the leads 204 via the electrical interconnect clip 100. In the half-bridge configuration, the connection provided by the die pad 202 to the first vertical power device die 206 may correspond to the first DC voltage connection, the connection provided by the second electrical interconnect clip 210 to the second vertical power device die 206 may correspond to the second DC voltage connection, and the connection provided between the first and second vertical power device dies 206 and the electrical interconnect clip 100 may correspond to the phase connection.

Forming the semiconductor package may comprise one or more soldering processes. These soldering processes include a soldering process that solders the first load terminal of the second vertical power device die 206 with the die interface portion 102 of the electrical interconnect clip 100 and thus electrically connects the two together. According to this process, a solder material is provided between the upper mating surface 107 of the electrical interconnect clip 100 and the load terminal of the second vertical power device die 206. This solder material may be a solder paste comprising a tin based and/or lead-free solder material, for example. The solder material may be initially applied on one or both of the upper mating surface 107 of the electrical interconnect clip 100 and the second vertical power device die 206, e.g., as a preform, solder ball, etc. With the second vertical power device die 206 intact and positioned in a desired location on the electrical interconnect clip 100, a heating process is performed whereby the temperature of the solder material is elevated to melt the material and induce a reaction whereby a stable soldered joint is formed. A peak temperature of this heating process occurs at a reflow phase of this heating process. Reflow temperatures for this soldering process may be in the range of 200° C. to 300° C., for example. This heating process may form additional soldered joints as well, including any of the soldered joints necessary to form the above-described electrical connections.

During the above-described soldering step, the solder retention feature 108 advantageously maintains the position of the second vertical power device die 206. In more detail, the solder retention feature 108 forms a border around the second vertical power device die 206 and interacts with liquified solder during the heating process by retaining the solder material within a confined space that surrounds the second vertical power device die 206. As a result, the liquified solder material gathers at the border around the perimeter of the second vertical power device die 206 and prevents floating movement of the second vertical power device die 206 during the reflow process. The gathering of the liquified solder material in the solder retention feature 108 forms a meniscus that prevents the second vertical power device die 206 from freely moving (floating) on the liquified solder material. In particular, the second vertical power device die 206 is prevented from moving rotationally from a plan-view perspective. By way of comparison, a rotational movement of 5 degrees or more has been observed in electrical interconnect clips that do not include the solder retention feature 108 described herein, which can potentially lead to problematic failure and/or semiconductor dies extending over the edge side of the electrical interconnect clip.

Advantageously, the solder retention feature 108 may eliminate the need for special plating on the electrical interconnect clip, such as Ag plating layers, that may be used to prevent floating movement of a semiconductor die but add cost and complexity. Thus, according to an embodiment, the surfaces of the electrical interconnect clip 100, and in particular the die attach area 112 may be surfaces of exposed base material metal, such as a bare copper, bare aluminum, and alloys thereof.

After mounting the dies and forming the electrical interconnections, an encapsulation process may be formed to cover the carrier, the semiconductor dies and associated electrical connections. Meanwhile, outer ends of the leads 204 remain exposed from the electrically insulating encapsulant body forming externally accessible package terminals. The encapsulation process may include forming an electrically insulating mold compound, e.g., by injection molding, transfer molding, compression molding, etc. A dicing process may be performed to form a complete semiconductor package.

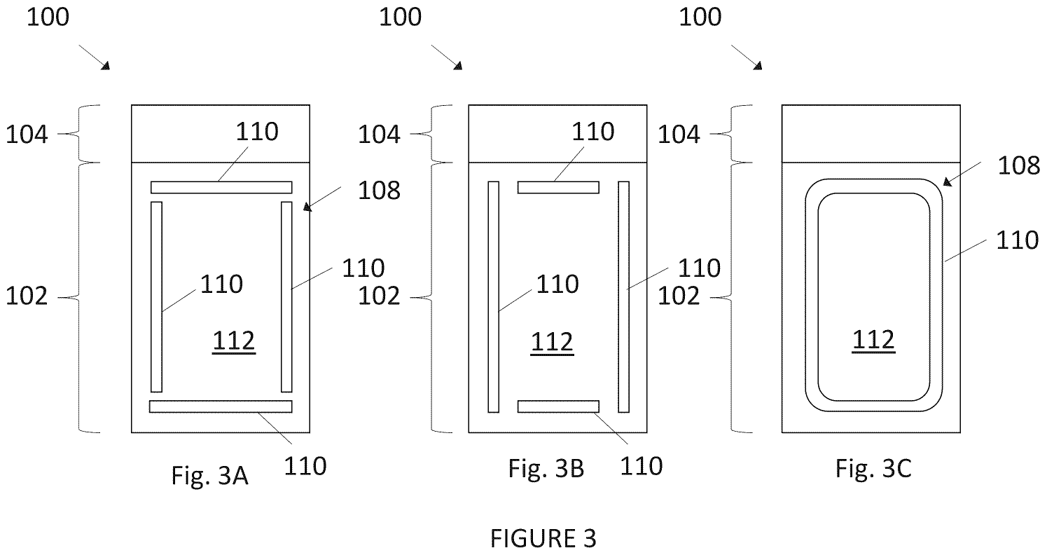

Referring to FIG. 3, additional embodiments of the electrical interconnect clip 100 are shown. The illustrated embodiments represent potential alternate configurations for the solder retention feature 108. In the embodiments of FIGS. 3A and 3B, the solder retention feature 108 is formed by a plurality of the grooves 110. In each case, the grooves 110 collectively form a border surrounding the die attach area 112 of the upper mating surface 107 and consequently surrounding the semiconductor die mounted thereon. The plurality of the grooves 110 work similarly as the single continuous groove 110 in the above-described embodiment by forming a border that retains the solder material within a confined space that surrounds the semiconductor die mounted thereon, and thereby prevents floating movement of this semiconductor die. The size of the interruptions between each of the grooves 110 is sufficiently small such that the liquified solder material gathers around the perimeter the semiconductor die mounted thereon and forms a meniscus that prevents floating movement of the semiconductor die mounted thereon during the soldering process. For example, the plurality of the grooves 110 may occupy at least 90%, at least 80% or at least 75% of the total length of an enclosed shape around the die attach area 112 and provide the necessary interaction with liquified solder to maintain the position of the die. Separately or in combination, the plurality of the grooves 110 may occupy at least 50% of the length of each side of the enclosed shape around the die attach area 112 and provide the necessary interaction with liquified solder to maintain the position of the die. FIGS. 3A and 3B illustrate just two potential configurations and more generally small interruptions may be provided at any location. FIG. 30 illustrates a solder retention feature 108 formed by a continuous groove 110 that forms an enclosed shape around the upper mating surface 107, wherein the enclosed shape has rounded corners. Different types of corner geometries and/or different enclosed shape geometries are possible as well. Moreover, the size of the grooves 110 may be adapted to a particular die size. Preferably, the footprint of the grooves 110 is slightly larger than the particular die that is intended to be mounted on the electrical interconnect clip 100.

As used herein, the term surround incudes completely continuous geometries that form an enclosed shape and non-continuous geometries that form an enclosed shape with interruptions. For instance, a rectangle with localized interruptions is a geometry that surrounds an interior area, provided that at least part of the interior area borders the rectangle on all four sides.

The semiconductor die disclosed herein can be formed in a wide variety of device technologies that utilize a wide variety of semiconductor materials. Examples of such materials include, but are not limited to, elementary semiconductor materials such as silicon (Si) or germanium (Ge), group IV compound semiconductor materials such as silicon carbide (SIC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), etc.

The semiconductor die disclosed herein may be configured as a vertical device, which refers to a device that conducts a load current between opposite facing main and rear surfaces of the die. Alternatively, the semiconductor die may be configured as a lateral device, which refers to a device that conducts a load current parallel to a main surface of the die.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

Example 1. An electrical interconnect clip, comprising: a die interface portion that is adapted for mating in between two vertically stacked semiconductor dies; and a carrier connection portion that is configured to electrically connect the two vertically stacked semiconductor dies with a carrier, wherein the die interface portion comprises: a lower mating surface; an upper mating surface opposite from the lower mating surface; and a solder retention feature formed by one or more grooves in the upper mating surface that are spaced apart from outer edge sides of the electrical interconnect clip and surround a die attach area of the upper mating surface.

Example 2. The electrical interconnect clip of example 1, wherein the solder retention feature is formed by a continuous one of the grooves that forms an enclosed shape around the die attach area of the upper mating surface.

Example 3. The electrical interconnect clip of example 2, wherein the continuous one the grooves forms a rectangle around the die attach area of the upper mating surface.

Example 4. The electrical interconnect clip of example 1, wherein the one or more grooves have v-shaped cross-sectional geometry.

Example 5. The electrical interconnect clip of example 4, wherein an intersection angle between sidewalls of the one or more grooves is between 50° and 70°.

Example 6. The electrical interconnect clip of example 1, wherein the one or more grooves have a depth of between 20 μm and 50 μm.

Example 7. The electrical interconnect clip of example 1, wherein the electrical interconnect clip is formed from a base metal of copper, aluminum, or alloys thereof, and wherein the die attach area of the upper mating surface is a bare surface of the base metal.

Example 8. A semiconductor package, comprising the electrical interconnect clip of claim 1.

Example 9. The semiconductor package of example 8, wherein the semiconductor package comprises first and second semiconductor dies mounted in a stacked die arrangement with the interface portion of the electrical interconnect clip arranged between the first and second semiconductor dies, and wherein the one or more grooves of the solder retention feature surround the second semiconductor die.

Example 10. The semiconductor package of example 9, wherein the first and second semiconductor dies are each configured as discrete transistor dies, wherein the first and second semiconductor dies are arranged in a half-bridge configuration, and wherein the electrical interconnect clip forms a phase terminal connection that electrically connects load terminals from the first and second semiconductor dies to one or more leads of the semiconductor package.

Example 11. A method of forming a semiconductor package, the method comprising: providing a carrier comprising a die pad and a plurality of leads; providing first and second semiconductor dies, each being configured as vertical power devices, providing an electrical interconnect clip that comprises a die interface portion and a carrier connection portion; proving a stacked die arrangement on the die pad that comprises the die interface portion of the electrical interconnect clip arranged between the first and second semiconductor dies and the carrier connection portion contacting the carrier; providing solder material in between the second semiconductor die and the die interface portion of the electrical interconnect clip; and performing a soldering process that liquifies the solder material, wherein the electrical interconnect clip comprises a solder retention feature that forms a border surrounding the second semiconductor die, and wherein the solder retention feature interacts with liquified solder during the soldering process by retaining the solder material within a confined space that surrounds the second semiconductor die, thereby preventing floating movement of the second semiconductor die.

Example 12. The method of example 11, wherein the solder retention feature is formed by one or more grooves in an upper mating surface of the die interface portion that are spaced apart from outer edge sides of the electrical interconnect clip and form a border surrounding a die attach area of the upper mating surface, and wherein the one or more grooves become at least partially filled by the liquified solder material during the soldering process.

Example 13. The method of example 12, wherein the liquified solder material that fills the one or more grooves during the soldering process forms a meniscus that prevents the floating movement of the second semiconductor die during the soldering process.

Example 14. The method of example 12, wherein the solder retention feature is formed by a continuous one of the grooves that forms an enclosed shape around the upper mating surface.

Example 15. The method of example 12, wherein the one or more grooves have v-shaped cross-sectional geometry.

Example 16. The method of example 15, wherein an intersection angle between sidewalls of the one or more grooves is between 50° and 70°.

Example 17. The method of example 12, wherein the one or more grooves have a depth of between 20 μm and 50 μm.

Example 18. The method of example 12, wherein the electrical interconnect clip is formed from a base metal of copper, aluminum, or alloys thereof, and wherein the die attach area of the upper mating surface is a bare surface of the base metal.

Example 19. The method of example 11, wherein the first and second semiconductor dies are each configured as discrete transistor dies, wherein the first and second semiconductor dies are arranged in a half-bridge configuration, and wherein the electrical interconnect clip forms a phase terminal connection that electrically connects load terminals from the first and second semiconductor dies to one or more of the leads.

Example 20. The method of example 19, further comprising providing a second electrical interconnect clip and electrically connecting a second load terminal of the second semiconductor die with the carrier via the second electrical interconnect clip.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An electrical interconnect clip, comprising:
a die interface portion that is adapted for mating in between two vertically stacked semiconductor dies; and
a carrier connection portion that is configured to electrically connect the two vertically stacked semiconductor dies with a carrier,
wherein the die interface portion comprises:
a lower mating surface;
an upper mating surface opposite from the lower mating surface; and
a solder retention feature formed by one or more grooves in the upper mating surface that are spaced apart from outer edge sides of the electrical interconnect clip and surround a die attach area of the upper mating surface.

2. The electrical interconnect clip of claim 1, wherein the solder retention feature is formed by a continuous one of the grooves that forms an enclosed shape around the die attach area of the upper mating surface.

3. The electrical interconnect clip of claim 2, wherein the continuous one the grooves forms a rectangle around the die attach area of the upper mating surface.

4. The electrical interconnect clip of claim 1, wherein the one or more grooves have v-shaped cross-sectional geometry.

5. The electrical interconnect clip of claim 4, wherein an intersection angle between sidewalls of the one or more grooves is between 50° and 70°.

6. The electrical interconnect clip of claim 1, wherein the one or more grooves have a depth of between 20 μm and 50 μm.

7. The electrical interconnect clip of claim 1, wherein the electrical interconnect clip is formed from a base metal of copper, aluminum, or alloys thereof, and wherein the die attach area of the upper mating surface is a bare surface of the base metal.

8. A semiconductor package, comprising the electrical interconnect clip of claim 1.

9. The semiconductor package of claim 8, wherein the semiconductor package comprises first and second semiconductor dies mounted in a stacked die arrangement with the interface portion of the electrical interconnect clip arranged between the first and second semiconductor dies, and wherein the one or more grooves of the solder retention feature surround the second semiconductor die.

10. The semiconductor package of claim 9, wherein the first and second semiconductor dies are each configured as discrete transistor dies, wherein the first and second semiconductor dies are arranged in a half-bridge configuration, and wherein the electrical interconnect clip forms a phase terminal connection that electrically connects load terminals from the first and second semiconductor dies to one or more leads of the semiconductor package.

11. A method of forming a semiconductor package, the method comprising:
providing a carrier comprising a die pad and a plurality of leads;
providing first and second semiconductor dies, each being configured as vertical power devices,
providing an electrical interconnect clip that comprises a die interface portion and a carrier connection portion;
proving a stacked die arrangement on the die pad that comprises the die interface portion of the electrical interconnect clip arranged between the first and second semiconductor dies and the carrier connection portion contacting the carrier;
providing solder material in between the second semiconductor die and the die interface portion of the electrical interconnect clip; and
performing a soldering process that liquifies the solder material,
wherein the electrical interconnect clip comprises a solder retention feature that forms a border surrounding the second semiconductor die, and
wherein the solder retention feature interacts with liquified solder during the soldering process by retaining the solder material within a confined space that surrounds the second semiconductor die, thereby preventing floating movement of the second semiconductor die.

12. The method of claim 11, wherein the solder retention feature is formed by one or more grooves in an upper mating surface of the die interface portion that are spaced apart from outer edge sides of the electrical interconnect clip and form a border surrounding a die attach area of the upper mating surface, and wherein the one or more grooves become at least partially filled by the liquified solder material during the soldering process.

13. The method of claim 12, wherein the liquified solder material that fills the one or more grooves during the soldering process forms a meniscus that prevents the floating movement of the second semiconductor die during the soldering process.

14. The method of claim 12, wherein the solder retention feature is formed by a continuous one of the grooves that forms an enclosed shape around the upper mating surface.

15. The method of claim 12, wherein the one or more grooves have v-shaped cross-sectional geometry.

16. The method of claim 15, wherein an intersection angle between sidewalls of the one or more grooves is between 50° and 70°.

17. The method of claim 12, wherein the one or more grooves have a depth of between 20 μm and 50 μm.

18. The method of claim 12, wherein the electrical interconnect clip is formed from a base metal of copper, aluminum, or alloys thereof, and wherein the die attach area of the upper mating surface is a bare surface of the base metal.

19. The method of claim 11, wherein the first and second semiconductor dies are each configured as discrete transistor dies, wherein the first and second semiconductor dies are arranged in a half-bridge configuration, and wherein the electrical interconnect clip forms a phase terminal connection that electrically connects load terminals from the first and second semiconductor dies to one or more of the leads.

20. The method of claim 19, further comprising providing a second electrical interconnect clip and electrically connecting a second load terminal of the second semiconductor die with the carrier via the second electrical interconnect clip.
